(19) United States
(12) Patent Application Publication
(10) Pub. No.: US 2026/0250122 A1
(43) Pub. Date: Aug. 27, 2026

(54) METHOD FOR PRODUCING A SILICON LAYER SYSTEM WITH ELECTRICAL CONNECTIONS

(71) Applicant: Robert Bosch GmbH, Stuttgart (DE)

(72) Inventors: Achim Harzheim, Tuebingen (DE); Arnd Kaelberer, Schlierbach (DE); Heiko Stahl, Reutlingen (DE); Jochen Tomaschko, Gaeufelden (DE); Hartmut Kueppers, Reutlingen (DE)

(21) Appl. No.: 18/994,091

(22) PCT Filed: Jul. 10, 2023
(86) PCT No.: PCT/EP2023/068975

§ 371 Date: Jan. 14, 2025

(30) Foreign Application Priority Data
Aug. 17, 2022 (DE) 10 2022 208 515.9

(51) Int. Cl. B81B 7/00; B81C 1/00

(52) U.S. Cl. CPC B81B 7/0006; B81C 1/0038; B81C 1/00476; B81C 1/00531

(57) ABSTRACT

A method for producing a silicon layer system. The method includes: providing a carrier substrate, the carrier substrate being provided with an insulation layer formed on its surface; applying a first silicon layer to the insulation layer;

structuring the first silicon layer to form trenches in the silicon layer at least in places extending through the silicon layer; passivating the first silicon layer; and structuring the passivation layer. The steps are repeated from the application step, as a result of which sacrificial regions and functional regions are produced in further silicon layers, and then all of the sacrificial regions are removed. The steps are carried out in such a way that an electrical connection including a specialized functional region is configured by means of which an electrical contact between two elements can be established, wherein the one specialized functional region is used only for the electrical connection.

### FIELD

The present invention applies to the field of silicon layer systems and relates to a method for producing a silicon layer system with electrical connections. It also relates to a silicon layer system and a microelectromechanical device comprising such a silicon layer system.

### BACKGROUND INFORMATION

The so-called EPyC process (EPyC: epitaxial polysilicon cycle) for producing microelectromechanical structures having a large vertical extension, which uses epitaxial polysilicon as a functional and sacrificial material and builds a layer structure of epitaxial polysilicon layers using repeating cycles, is described in Germany Patent Application No. DE 10 2015 206 996 A1. U.S. Patent Application Publication Nos. US 2014/0117469 A1 and US 2018/0111823 A1 deal with the combination of MEMS (microelectromechanical systems) and TSVs (through-silicon vias).

### SUMMARY

According to the present invention, a method for producing a silicon layer system with electrical connections, a corresponding silicon layer system and a microelectromechanical device comprising such a silicon layer system are provided.

According to a first aspect of the present invention, a method for producing a silicon layer system with electrical connections is provided, which can, for instance, comprise structures for a microelectromechanical device such as a MEMS (microelectromechanical system). According to an example embodiment of the present invention, the method includes providing a carrier substrate, which can consist substantially of silicon, for example. An insulation layer is formed on a surface of the carrier substrate, wherein the insulation layer itself is not part of the carrier substrate. Such an insulation layer serves to provide electrical and mechanical insulation between the substrate and the silicon layer of the following first EPyC cycle.

The insulation layer is preferably a silicon oxide and/or silicon nitride layer. The insulation layer preferably serves as an etch stop layer for later silicon sacrificial layer etching. The use of such an etch stop layer eliminates the need for complex and highly variable time-dependent etching processes. In particular in order to produce electrical connections through the insulation layer, the insulation layer can already be structured and/or can undergo structuring prior to the implementation of the further steps.

A first silicon layer is applied to the insulation layer; for example bonded, sputtered and/or preferably grown, in particular epitaxially grown. Epitaxial growth in particular takes place at temperatures that are typically >600° C., preferably >900° C. Structuring of the insulation layer can take place prior to this application of the first silicon layer and/or after the removal of the carrier substrate, i.e. from the opposite side. The applied first silicon layer can comprise or be a monocrystalline, a polycrystalline and/or an epi-polycrystalline silicon layer, for instance. The term epi-polycrystalline silicon layers refers to polycrystalline silicon layers that have been grown epitaxially, i.e. under epitaxial growth conditions. Such epi-polycrystalline silicon layers typically have thicknesses of more than 5 μm, often also several 10 μm.

Epitaxial growth on the insulation layer, for example a silicon oxide layer, can include prior application of a polysilicone starting layer, for example via CVD polysilicon deposition (CVD: chemical vapor deposition), onto the insulation layer, because polysilicon (polycrystalline silicon) typically cannot be epitaxialized directly on the insulation layer. This also applies to the passivation layers discussed below. Regions that are not covered by the insulation layer or a passivation layer can be filled by CVD polysilicon deposition which creates electrical contact with a silicon layer to be grown later. The result of this is the formation of a wiring layer. However, direct epitaxialization without a polysilicon starting layer can also be made possible by selecting a process control in which crystallization nuclei form by themselves. In the context of this invention, the term epitaxial growth refers to both possible variants; i.e. indirect epitaxial growth using a starting layer to be applied at least in part beforehand and direct epitaxial growth without a starting layer.

A carrier substrate comprising a silicon layer applied to an insulation layer can also be provided directly in the form of a raw wafer, such as an SOI wafer (SOI: silicon-on-insulator). A layer thickness of the first silicon layer and also of further applied silicon layers can be 0.5 to 100 μm, preferably 20 to 60 μm, for example.

This first silicon layer is structured to form trenches in the first silicon layer, wherein the trenches extend at least in places through the first silicon layer. Such structuring can be carried out by means of reactive ion etching (RIE) and/or deep reactive ion etching (DRIE), for example, and/or, in particular in the case of relatively thin silicon layers, by means of a plasma etching process.

The first silicon layer is then passivated, wherein the trenches are filled and a first passivation layer forms on a side of the first silicon layer facing away from the insulation layer. The trenches are filled here by forming the first passivation layer in the trenches. The passivation layer preferably covers substantially the entire surface of the first silicon layer including the trenches. Passivation techniques such as thermal oxidation and/or tetraethyl orthosilicate deposition (TEOS deposition), silicon carbide deposition (SiC deposition), silicon carbonitride deposition (SiCN deposition), silicon nitride deposition (SiₓN_{y} deposition) or silicon oxynitride deposition (SiON deposition) can be used for passivation. Regions of the silicon layer that are not to be etched are protected from etching attack by the passivation layer. The regions of the silicon layer with access for an etching medium used for etching (sacrificial regions) can be etched completely. The passivation layer thus serves as a lateral and vertical etch stop, and can therefore have a function identical to that of the insulation layer. The produced passivation layers can be made of different materials depending on the passivation technique used; for example silicon oxide and/or silicon nitride. For instance, an oxide etching process can preserve the parts of the passivation layers that consist of silicon nitride, which can then be used for electrical insulation during operation of the layer system produced by the process.

The first passivation layer formed in this way is structured, wherein this structuring results in the formation of first sacrificial regions and functional regions in the first silicon layer and the first sacrificial regions on the side of the first silicon layer facing away from the insulation layer are free of the first passivation layer at least in places.

After structuring the first passivation layer, the steps of applying, for example epitaxial growth, structuring and passivating the first silicon layer as described above are all repeated. The structuring of the first passivation layer is also repeated as described above. Such repetition can occur several times, for example twice, three times, five times or ten times. In the context of such a repetition, the application is always carried out on a structured passivation layer (namely the currently outermost layer) instead of the insulation layer. As a result, further silicon layers and further passivation layers are formed and structured. Forming and structuring the further silicon layers and the further passivation layers creates further sacrificial regions and further functional regions in the further silicon layers. Structuring the further passivation layers also makes it possible to achieve electrical connections and insulation between specific regions of the silicon layers. The stacked layers can be precisely aligned with one another. Every silicon layer can be structured and configured independently of other silicon layers. Interlocking and/or overlapping functional regions, in particular with respect to a vertical extension, are in particular possible too. The method also makes it possible to freely design electrical connections and insulation and mechanical connections and insulation within the functional regions. As part of this procedure, regions that are free of a passivation layer can be filled prior to the application of the next silicon layer by means of CVD polysilicon deposition in order to form a wiring layer. Such CVD polysilicon deposition can also be used to produce a starting layer during the step of applying the next silicon layer.

According to an example embodiment of the present invention, the steps of applying, structuring and passivating the silicon layers, including the first silicon layer, and also structuring the passivation layers, including the first passivation layer, are carried out in such a way that an electrical connection is configured within the at least one specialized functional region of the silicon layer system being formed, wherein the electrical connection can be used to establish an electrical contact between two elements inside and/or outside the silicon layer system, wherein the at least one specialized functional region is still used only for the electrical connection. A specialized functional region here is a functional region formed by the method steps. An electrical connection configured in this way can consist entirely of specialized functional regions that are used only for the electrical connection. The two elements can be internal and/or external elements. Internal elements can, for instance, be functional regions that are not specialized for electrical current conduction, i.e. that can be or are themselves part of an electrode, an actuator and/or a sensor, for example. An external element can be an external power and/or signal source, for instance, for example an electronic control unit, with an external electrical connection, for example a wire or a solder contact, that is connected to the silicon layer system. Such an external electrical connection itself, such as a wire or a solder contact, constitutes an external element as well. The elements are therefore generally electrical functional elements. Lastly, all of the sacrificial regions are removed, typically by means of an etching process (silicon sacrificial layer etching).

Therefore, according to the present invention a method for forming electrical connections in a silicon layer system of any size is provided. According to the present invention, this method makes uses the EPyC process. For further details regarding the EPyC process, please refer to Germany Patent Application No. DE 10 2015 206 996 A1, which is hereby incorporated in its entirety as part of the present application.

In a preferred embodiment of the method according to the present invention, the electrical connection is or comprises an electrical connection which extends vertically (perpendicular to the surface of the carrier substrate), wherein the vertically extending electrical connection consists of or comprises a plurality of specialized functional regions of the functional regions which are disposed one above the other, wherein the plurality of specialized functional regions are used only for the electrical connection. The electrical connection can also be or comprise a horizontally extending electrical connection.

The terms vertical and horizontal are intended to be understood here in relation to the surface of the carrier substrate which is provided with the insulation layer. A horizontally extending electrical connection is an electrical connection that is used to conduct current horizontally in the sense that the direction of the current (current direction) deviates from a substantially vertical direction, i.e., extends parallel or at an angle to the surface of the carrier substrate, for example. Such a horizontally extending electrical connection consequently comprises a functional region that is specialized for electrical current conduction and is in electrical contact with other functional regions or other elements inside and/or outside the silicon layer system, wherein these electrical contacts are not disposed vertically one above the other but are instead laterally offset to one another. A functional region that is part of a horizontally extending electrical connection can in particular also be part of a vertically extending electrical connection; for example if said functional region comprises three or more electrical contacts to surrounding further functional regions, if two of these electrical contacts are disposed vertically relative to one another and the third is laterally offset to the other two.

According to an example embodiment of the present invention, preferably after the removal of all of the sacrificial regions, the first passivation layer and/or one or more of the further passivation layers are removed as well, at least in places, which possibly also includes exposing trenches and/or the insulation layer, for example in order to produce a desired mobility of the produced structures. This is advantageous in particular when the functional regions are advantageously completely fixed relative to one another by the method according to the present invention. Recesses and/or openings can be created in one of the produced passivation layers and/or trenches can be exposed, for instance. The passivation layer can also be removed completely. This can include exposing the trenches. The passivation layer, or parts thereof, can be removed by gas-phase etching, plasma etching and/or wet etching, for example. The passivation layer or parts thereof can thus be removed particularly easily.

The produced passivation layers can be made of different materials depending on the passivation technique used; for example silicon oxide and/or silicon nitride. According to a preferred embodiment of the method of the present invention, it is particularly advantageous if one of the passivation layers consists at least in places of a first material and one of the passivation layers and/or the insulation layer consists at least in places of a second material. This can be achieved by using two different passivation techniques for passivating the silicon layers, so that the passivation layers or regions of the passivation layers are made of two different materials. Thermal oxidation and/or TEOS deposition can be used as a first passivation technique and silicon nitride deposition as a second passivation technique, for example, which makes it possible to create passivation layers comprising a first part made of silicon oxide and a second part made of silicon nitride. This includes the possibility that passivation layers can also consist of silicon oxide in places and silicon nitride in places. This embodiment of the method according to the present invention makes it possible to leave the part of the passivation layers that are made of the second material, for example silicon nitride, by selecting the method for removing the parts of the passivation layers made of the first material, for example silicon oxide, accordingly. This makes it possible to easily and selectively ensure electrical insulation between different functional regions, since both silicon oxide and silicon nitride are dielectrics. An oxide etching process, for instance, can preserve the parts of the passivation layers that consist of silicon nitride, which can then be used for electrical insulation during operation of the layer system produced by the process.

In an advantageous example embodiment of the method according to the present invention, the carrier substrate is removed as well. The produced layer system can thus be used independently of the carrier substrate. Such removal preferably takes place prior to the removal of all of the remaining sacrificial regions (typically by means of silicon sacrificial layer etching). The carrier substrate is preferably removed by means of chemical-mechanical polishing (CMP).

According to an example embodiment of the present invention, preferably at least one of the applied silicon layers, for example the first silicon layer and/or one of the further silicon layers, comprises or is a monocrystalline, a polycrystalline and/or an epi-polycrystalline silicon layer. A layer thickness of at least one of the applied silicon layers, for example the first silicon layer and/or the second silicon layer and/or one of the further silicon layers, can furthermore be 0.5 to 100 μm, for instance, preferably 20 to 60 μm. Thin silicon layers are suitable in MEMS as resilient elements for vertical deflections, for example. Thick silicon layers, on the other hand, are advantageous for producing electrode combs or also for filling large volumes or for removing them as sacrificial regions.

The structuring to form the trenches is preferably carried out using a trench process such as reactive ion etching (RIE) and/or deep reactive ion etching (DRIE) and/or using a plasma etching process. A plasma etching process is useful in particular for thin layers (thicknesses of a few micrometers). For thicker layers, DRIE can be used, for example.

According to a preferred configuration of the method according to the present invention, the passivation layers are structured using a dry etching process and/or a wet etching process. The passivation layers can thus be easily removed again without having to resort to a specific etching process.

It is furthermore advantageous if chemical-mechanical polishing (CMP) and/or, at least in places, additional doping by implantation and/or coating of this silicon layer takes place after the application of one of the silicon layers. In particular topological irregularities and height differences that occur in the case of epitaxial growth of the silicon layer can thus easily be planarized. Additional doping by implantation or coating makes it easy to set a desired conductivity in the silicon layer or in specific regions of it. The grown silicon layers can be undoped, p-doped or n-doped. Such a procedure is particularly suitable for achieving particularly good conductivity of the specialized functional regions in the electrical connection to be configured.

The sacrificial regions are preferably removed at least partly by plasmaless and/or plasma-assisted etching, i.e. by means of silicon sacrificial layer etching processes. This makes it particularly easy to remove the sacrificial regions. Such plasmaless etching can be carried out using chlorine trifluoride (CIF₃), chlorine fluoride (CIF), chlorine pentafluoride (CIF₅), bromine trifluoride (BrF₃), bromine pentafluoride (BrF₅), iodine pentafluoride (IF5), iodine heptafluoride (IF;), sulfur tetrafluoride (SF₄), xenon difluoride (XeF₂) or similar substances, for example. Plasma-assisted etching can be carried out using fluorine plasma, chlorine plasma, and/or bromine plasma, for instance. Etching can in particular also be based on a combination of plasmaless and plasma-assisted etching.

According to a second aspect of the present invention, a silicon layer system is provided, for example for a microelectromechanical device comprising a MEMS such as a micromirror array. According to an example embodiment of the present invention, the silicon layer system preferably comprises microelectromechanical structures produced using a method according to the present invention, is provided. The microelectromechanical device has an alternating sequence of structured silicon layers with functional regions and structured passivation layers and an electrical connection comprising or consisting of a specialized functional region of the functional regions. The electrical connection can be used to establish an electrical contact between two elements inside and/or outside the silicon layer system, wherein the specialized functional region is used only for the electrical connection.

According to an example embodiment of the present invention, in such a layer system, the electrical connection can be or comprise a vertically extending electrical connection, which consists of or comprises a plurality of specialized functional regions of the functional regions that are disposed one above the other, wherein the plurality of specialized functional regions are used only for the electrical connection. The electrical connection can alternatively or simultaneously also be or comprise a horizontally extending electrical connection.

According to a third aspect of the present invention, a microelectromechanical device comprising a silicon layer system according to the present invention is provided.

The method according to the present invention easily makes it possible to design a silicon layer system with electrical connections, in particular TSVs (through-silicone vias). A significant advantage of the method according to the present invention is its high degree of flexibility and variability.

The use of the method is therefore particularly advantageous in the production of microelectromechanical structures for microelectromechanical devices, because this typically requires a high degree of variability of the method used for electrical interconnection with respect to the dimensions of these interconnections: Both the selection of the dimensions of the electrical connections and the insulation structures and the routing thereof has to be flexible. This is made possible by the method according to the present invention. The method is suitable in particular for cabling structures and TSVs that a large horizontal and vertical extension.

The method does not require any complex intermediate steps for the placement of electrical connections. There is in particular no need for additional lithography and/or structuring steps as is in particular the case when producing separate TSVs. The method integrates the production of the actual silicon layer system, for example the microelectromechanical structures, with the creation of the electrical connections between desired elements. The process according to the present invention is moreover suitable for CMOS and high temperatures and is therefore in particular suitable for mass production, for instance of MEMS. The high temperature tolerance in particular also makes drive-in steps and annealing unproblematic.

### BRIEF DESCRIPTION OF THE DRAWINGS

Example embodiments of the present invention are explained in more detail with reference to the figures and the following description.

FIGS. 1A and 1B show schematic cross-sectional views to illustrate a method according to an example embodiment of the present invention for producing a silicon layer system with electrical connections.

FIG. 2 shows a schematic flow chart to illustrate a method according to an example embodiment of the present invention for producing a silicon layer system with electrical connections.

FIG. 3 shows a schematic illustration of an example of a microelectromechanical device according to an example embodiment of the present invention.

### DETAILED DESCRIPTION OF EXAMPLE EMBODIMENTS

In the following description of the embodiments of the present invention, identical or similar elements are denoted by identical reference signs, wherein a repeated description of these elements is omitted in individual cases. The figures show the subject matter of the present invention only schematically.

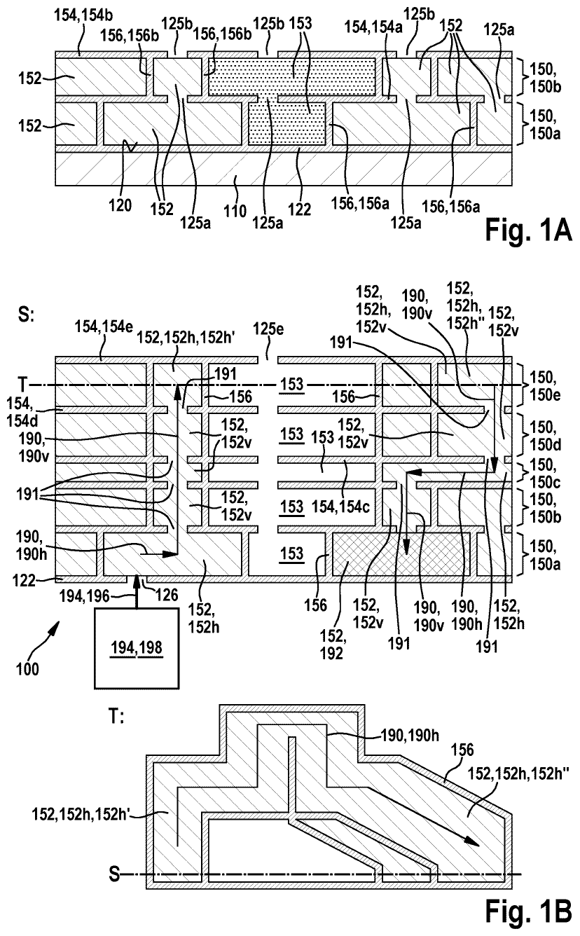

FIGS. 1A and 1B show schematic cross-sectional views to illustrate an example of a method according to the present invention for producing microelectromechanical structures. For the sake of clarity, the insulation layers and the passivation layers (both inside and outside the drawn trenches) are shown in the same way in the figures. All of the layers shown in the figures as two-dimensional objects also have a third spatial dimension and can be structured along this dimension as well by the method according to the present invention, which enables an extremely high degree of flexibility.

FIG. 1A shows a provided carrier substrate 110. Also shown is an insulation layer 122, for example made of silicon oxide, that was applied to a surface 120 of the first carrier substrate 110.

Using a method according to the present invention, a first silicon layer 150a was applied to the insulation layer 122, for example epitaxially grown, and then structured. This created trenches 156a that extend through the first silicon layer 150a. Passivating the first silicon layer 150a filled the trenches 156a and at the same time also formed a first passivation layer 154a on a side facing away from the insulation layer 122. This first passivation layer 154a, too, was structured (recesses 125a), which creates functional regions 152 and sacrificial regions 153 in the first silicon layer 150a. This ensures that the sacrificial regions 153 can be removed later by means of an etching process with an etching medium, wherein the regions of the silicon layers 150 act as sacrificial regions 153 that have access to the etching medium. These steps of applying 220, structuring 230 and passivating 240 of the first silicon layer 150a were then repeated one more time. A further silicon layer 150b was applied to the first passivation layer 154a, which filled the recesses 125a in the first passivation layer 154a.

This further silicon layer 150b was structured with further trenches 156b. These trenches 156b were filled by passivation and a further passivation layer 154b was created outside the trenches 156b as well. The further passivation layer 154b was then structured (recesses 125b). Both applied silicon layers 150a, 150b are labeled here with a common reference sign 150; the common reference sign 156 identifies the filled trenches, the common reference sign 154 identifies the passivation layers outside the trenches.

Further silicon layers 150 can be applied, structured and passivated, wherein the functional regions 152 and the sacrificial regions 153 are defined by the structuring of the passivation layers 154. FIG. 1B shows the silicon layer system 100 produced using the method according to the present invention with an electrical connection 190, wherein, compared to FIG. 1A, three further applied and structured silicon layers 150c, 150d, 150e with trenches 156 and correspondingly three further structured passivation layers 154c, 154d, 154e are shown.

Lastly, in FIG. 1BF, the carrier substrate 110 has been removed, and the produced structures can now be exposed completely by removing the sacrificial regions 153, for example by means of plasmaless and/or plasma-assisted etching. The regions of the silicon layers 150 with access to the etching medium used in this etching process, for example via the recess 125e of the passivation layer 154e, i.e. the sacrificial regions 153, are etched completely. Lastly, depending on the requirements, the passivation layers 154 can be removed at least partly, including exposure of the trenches 156 and/or the insulation layer 122 (not shown in FIG. 1B), for example in order to produce a desired mobility of the produced microelectromechanical structures. Such a removal can be carried out by gas-phase etching, plasma etching, or wet etching, for instance.

As shown in the upper subfigure of FIG. 1B (side view, labeled S), electrical connections 190 can be configured by appropriate structuring of the silicon layers 150. These electrical connections 190 can include specialized functional regions 152. FIG. 1B specifically shows an electrical connection 190 (illustrated as a plurality of arrows symbolizing a current direction of the electrical connection 190) which extends from a first electrical element 194 positioned outside the silicon layer system 100 to a second electrical element 192 inside the silicon layer system 100. This electrical connection 190 comprises a plurality of sections in which the current is conducted vertically and a plurality of sections in which it is conducted horizontally, in each case with respect to the surface 120 of the carrier substrate 110 which has since been removed. More specifically, five functional regions 152v specialized for electrical current conduction are part of three vertically extending electrical connections 190v, and three functional regions 152h specialized for electrical current conduction are part of three horizontally extending electrical connections 190h. The specialized functional regions 152 are in electrical contact via the filled recesses 191. Together, these specialized functional regions 152 form the electrical connection 190 between the external element 194 and the internal element 192, in which case the external element 194 can be an electronic control unit 198 with a connecting wire 196, for instance. The connecting wire 196 itself also constitutes an external element within the meaning of the present invention. In the shown example, the insulation layer 122 was removed in one location (recess 126) to connect the external element 194. The current direction is symbolized by the arrow shape of the connecting wire 196 of the electrical element 194. The internal element 192, which has been graphically emphasized in FIG. 1B by a different hatching for better identification, can, for instance, be a sensor, an electrode and/or actuator implemented by means of one or more functional regions 152 of the silicon layer system 100. For the sake of clarity, only the electrical connection 190 for the current direction toward the internal element 192 has been shown for FIG. 1B; a complete electrical circuit is not shown. It should be noted that, even though the internal element 192 is shown in FIG. 1B in the outermost first silicon layer 150a, this is purely to illustrate the possibility of more complex electrical connections 190 and is typically not the case in practice. The use of the present invention is actually particularly advantageous when no simple, direct access to an internal element 192 is possible (as would be the case here via the insulation layer 122); i.e. the internal element 192 to be coupled to an electrical connection 190 is disposed further inside a silicon layer system 100 to be produced.

In the uppermost silicon layer 150e there is a specialized functional region 152h, which is shown in the upper subfigure S only as two subregions 152h′ and 152h″. The lower subfigure T shows a section through the uppermost silicon layer 150e, the path of which in the upper subfigure S is marked by a dashed line. As shown, the electrical connections 190 and their specialized functional regions 152 do not have to be in a straight line, but can take any shape. To illustrate, the lower subfigure includes a dashed line S that shows the position of the plane shown in the subfigure S.

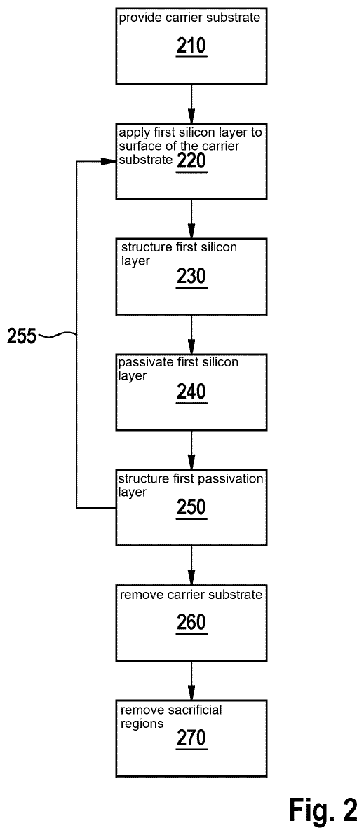

FIG. 2 shows a schematic flow chart to illustrate an example method according to the present invention for producing a silicon layer system 100 with electrical connections 190. After providing 210 a carrier substrate 110, a first silicon layer 150a is applied 220 to a surface 120 of this carrier substrate 110, for example epitaxially grown. This first silicon layer 150a is then structured 230 by forming trenches 156 that extend at least in places through the first silicon layer 150a. After passivating 240 the first silicon layer 150a, which is accompanied by filling the trenches 156, a first passivation layer 154a also forms outside the trenches 156. This is disposed on the side of the first silicon layer 150a facing away from the insulation layer 122. The thus created first passivation layer 154a is now structured in step 250 to define functional regions 152 and sacrificial regions 153. These steps for forming structured applied silicon layers 150 can now be repeated as often as desired. This is symbolized by arrow 255.

The steps 220 to 250 are each carried out in such a way that an electrical connection 190 comprising at least one specialized functional region 152h, 152v is configured by means of which an electrical connection between two elements 192, 194 inside and/or outside the silicon layer system 100 can be established, wherein the at least one specialized functional region 152h, 152v is used only for the electrical connection 190.

Once all of the desired silicon layers 150 are applied, the carrier substrate 110 is removed (step 260) and the sacrificial regions 153 are then removed in step 270 using a silicon sacrificial layer etching process. This can optionally also be followed by gas-phase etching, plasma etching and/or wet etching to at least partly remove the passivation layers 154.

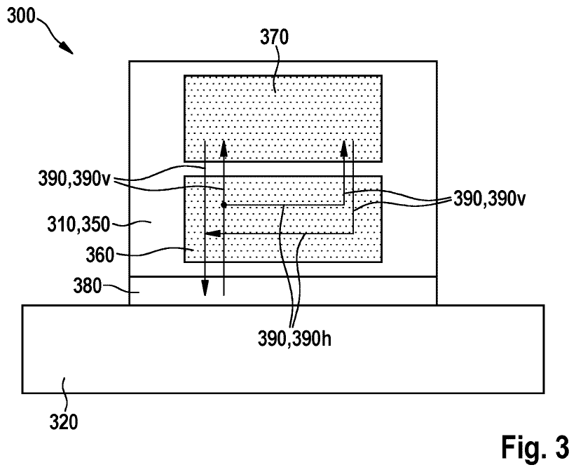

FIG. 3 shows a schematic illustration of an example of a microelectromechanical device 300 according to the present invention, for example comprising a MEMS. The microelectromechanical device 300 comprises a silicon layer system 310 that was produced according to a method according to the present invention. This silicon layer system 310 comprises an alternating sequence 350 of structured silicon layers 150 with functional regions 152 and structured passivation layers 154. Electrical connections 390 which consist of specialized functional regions 152h, 152v of the silicon layers 150 are moreover configured in the silicon layer system 310, wherein the electrical connections 390 can be used to establish an electrical contact between an internal element 370, for example an actuator, which is realized by functional regions 152 of the silicon layer system 310, and an external element 380, for example an electronic control unit 198 with connecting wire 196. The specialized functional regions 152h, 152v are used here only for the electrical connection 390.

In the shown example, the electrical connections 390 comprise vertically extending electrical connections 390v and horizontally extending electrical connections 390h. The silicon layer system 310 can also be used to realize a circuitry 360 comprising a plurality of electrical connections 390, for instance. The microelectromechanical device 300 is disposed on a carrier 320, which can, for instance, include further electrical and electronic components that are used to control the microelectromechanical device 310.

The present invention is not limited to the embodiment examples described here and the aspects highlighted therein. Rather, within the range of the present invention, a large number of modifications are possible which lie within the abilities of a person skilled in the art.

1-10. (canceled)

11. A method for producing a silicon layer system with electrical connections, comprising the following steps:
a) providing a carrier substrate including a surface. wherein the carrier substrate is provided with an insulation layer formed on the surface;
b) applying a first silicon layer to the insulation layer;
c) structuring the first silicon layer to form trenches in the first silicon layer, wherein the trenches extend at least in places through the first silicon layer;
d) passivating the first silicon layer, wherein the trenches are filled and a first passivation layer forms on a side of the first silicon layer facing away from the insulation layer;
e) structuring the first passivation layer, wherein first sacrificial regions and functional regions form in the first silicon layer and the first sacrificial regions on the side of the first silicon layer facing away from the insulation layer are free of the first passivation layer at least in places;
f) repeating steps b) to e) once or several times, wherein the applying is carried out in each case on a structured passivation layer thus forming and structuring further silicon layers and further passivation layers, as a result of which further sacrificial regions and further functional regions are created in the further silicon layers; and
g) removing all of the first and further sacrificial regions after repeating steps b) to e) once or several times;
wherein steps b) to f) are carried out in such a way that an electrical connection including at least one specialized functional region is configured by means of which an electrical contact between two elements inside and/or outside the silicon layer system can be established, wherein the at least one specialized functional region is used only for the electrical connection.

12. The method according to claim 11, wherein the electrical connection:
includes a vertically extending electrical connection which includes a plurality of specialized functional regions of the functional regions which are disposed one above the other, wherein the plurality of specialized functional regions are used only for the electrical connection; and/or
includes a horizontally extending electrical connection.

13. The method according to claim 11, wherein one of the first and further passivation layers includes, at least in places, a first material, and one of the passivation layers and/or the insulation layers includes at least in places of a second material.

14. The method according to claim 11, wherein a removal of the carrier substrate takes place, which is carried out prior to the removal of the first and further sacrificial regions and/or using chemical-mechanical polishing.

15. The method according to claim 11, wherein the first and further passivation layers are structured using a dry etching process and/or a wet etching process.

16. The method according to claim 11, wherein after the application of one of the first and further silicon layers, chemical-mechanical polishing and/or, at least in places, additional doping by implantation and/or coating of the at least one of the first and further silicon layer takes place.

17. The method according to claim 11, wherein the first and further sacrificial regions are removed at least in part by plasmaless and/or plasma-assisted etching.

18. A silicon layer system, comprising:
an alternating sequence of structured silicon layers with functional regions and structured passivation layers and an electrical connection including a specialized functional region of the functional regions, wherein the electrical connection can be used to establish an electrical contact between two elements inside and/or outside the silicon layer system, and wherein the specialized functional region is used only for the electrical connection.

19. The silicon layer system according to claim 18, wherein the electrical connection:
includes a vertically extending electrical connection which includes a plurality of specialized functional regions of the functional regions which are disposed one above the other, wherein the plurality of specialized functional regions are used only for the electrical connection; and/or
includes a horizontally extending electrical connection.

20. A microelectromechanical device, comprising:
a silicon layer system including:
an alternating sequence of structured silicon layers with functional regions and structured passivation layers and an electrical connection including a specialized functional region of the functional regions, wherein the electrical connection can be used to establish an electrical contact between two elements inside and/or outside the silicon layer system, and wherein the specialized functional region is used only for the electrical connection.
